(19) United States
(12) Patent Application Publication
(10) Pub. No.: US 2008/0266798 A1
(43) Pub. Date: Oct. 30, 2008

(54) SYSTEM AND METHOD FOR LIQUID COOLING OF AN ELECTRONIC SYSTEM

(75) Inventors: Eric A. Eckberg, Rochester, MN (US); James D. Gerken, Zumbro Falls, MN (US); Laurie Gerken, Zumbro Falls, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/740,026

(22) Filed: Apr. 25, 2007

(51) Int. Cl. H05K 7/20

(52) U.S. Cl. 361/699

(57) ABSTRACT

A liquid cooled electronic system and method includes a first component rotably connected to a second component via a coolant pathway. The coolant pathway includes at least one hinge assembly disposed and configured to convey coolant from the first component through the hinge assembly to the second component. The hinge assembly includes a first hinge portion in operable communication with the first component, a second hinge portion in operable communication with the second component; and a hinge pin disposed and configured to convey fluid therethrough and connecting the first hinge portion to the second hinge portion.

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention generally relates to electronic components. Specifically, this invention relates to liquid cooling systems for electronic components.

2. Description of Background

Electronic systems may produce an amount of heat during their operation that must be dissipated to ensure the continued operability of the components. Previously, air driven cooling systems have been adequate to dissipate heat from the components. As the capacity and capabilities of electronic components have increased, the heat generated by the components may exceed the heat dissipative capabilities of air cooling systems. As a consequence, liquid cooling systems (systems that rely on liquid to dissipate heat from components) have become more widely used because of their increased heat dissipation capability over air cooling systems.

In liquid cooling systems, conduits are used to convey liquid coolant, for example, chilled water, between various electronic components of, for example, a server rack, and/or between a liquid coolant source and the system or component to be cooled. Often it is advantageous for the various components to move relative to one another, thus a hinge is disposed between the components to facilitate the relative motion. For example, a first component may be disposed on a hinged door of a rack, while a second component is disposed within the rack. To convey coolant from the first component to the second component or vice-versa, a length of conduit must be connected to the two components. Because of the relative motion between the components, the conduit must be flexible and requires an excessive length, or loop, to allow the components to exercise their relative motion. This additional loop of conduit takes up space within the rack that could be utilized in other ways. Further, relative motion of the components induces stresses in the conduit and connectors leading to potential failure of the conduit and the cooling system.

### SUMMARY OF THE INVENTION

The shortcomings of the prior art are overcome and additional advantages are provided through a liquid cooled electronic system including a first component rotably connected to a second component via a coolant pathway. The coolant pathway includes at least one hinge assembly disposed and configured to convey coolant from the first component through the hinge assembly to the second component. The hinge assembly includes a first hinge portion in operable communication with the first component, a second hinge portion in operable communication with the second component; and a hinge pin disposed and configured to convey fluid therethrough and connecting the first hinge portion to the second hinge portion.

A method of cooling an electronic system includes urging coolant from a first component into a hinge assembly and flowing the coolant through the hinge assembly and into a second component. Heat is transferred from the second component into the coolant and the coolant is removed from the second component.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### Technical Effects

As a result of the summarized invention, technically we have achieved a solution which significantly decreases a length of conduit needed to connect a first component to a second component. This reduction in the length of conduit results in an increase in available space in the electronic system which may be utilized for other purposes. Additionally, since the conduit connections between the first component and the second component are fixed, stresses are reduced on the conduits and the connections, thereby increasing their useful life.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a partially exploded perspective view of an embodiment of a hinge; and

FIG. 2 depicts an embodiment of an electronic system utilizing the hinge of FIG. 1.

The detailed description explains the preferred embodiments of the invention, together with advantages and features, by way of example with reference to the drawings.

### DETAILED DESCRIPTION OF THE INVENTION

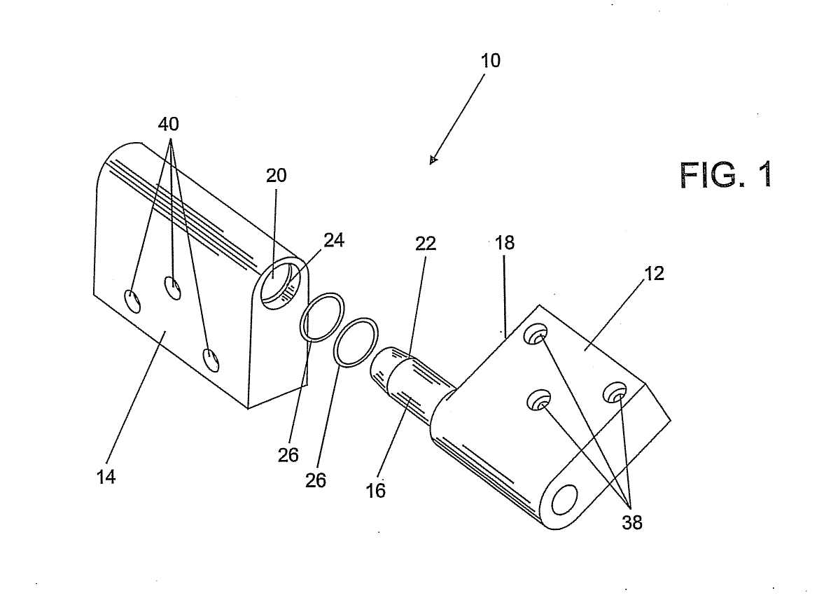

Turning now to the drawings in greater detail, FIG. 1 illustrates an embodiment of a hinge 10 capable of conveying liquid coolant for a liquid cooling system of electronic components. The hinge 10 comprises a male section 12 attached to a female section 14. The male section 12 may be substantially hollow, or may include an array of passageways (not shown) to carry fluid within the male section 12. The male section 12 includes a hinge pin 16 extending from an end 18 of the male section 12. The hinge pin 16 is substantially hollow and is configured to mate with a corresponding pin hole 20 in the female section 14 along a common longitudinal axis. In some embodiments, the hinge pin 16 is connected utilizing a barb connection. In those embodiments, the hinge pin 16 is configured with one or more barbs 22 that extend circumferentially around the hinge pin 16. The barbs 22 interlock with corresponding ridges 24 in the pin hole 20 to connect the male section 12 to the female section 14. Alternatively, some embodiments may include a threaded connection or other type of connection to connect hinge pin 16 to pin hole 20, and thus connect the male section 12 to the female section 14. The hinge 10 may include one or more o-rings 26 to make the connection between the male section 12 and female section 14 substantially leak-free. In the embodiment shown in FIG. 1, two o-rings 26 are provided, but other quantities of o-rings 26 and/or other means of accomplishing a leak-free seal may be provided and is contemplated within the scope of this invention. Further, the hinge pin 16 may be formed integrally with the male section 12 as shown in the embodiment of FIG. 1, or alternatively the hinge pin 16 may be formed separately from the male section 12 and assembled to the male section 12 by one of the means described above.

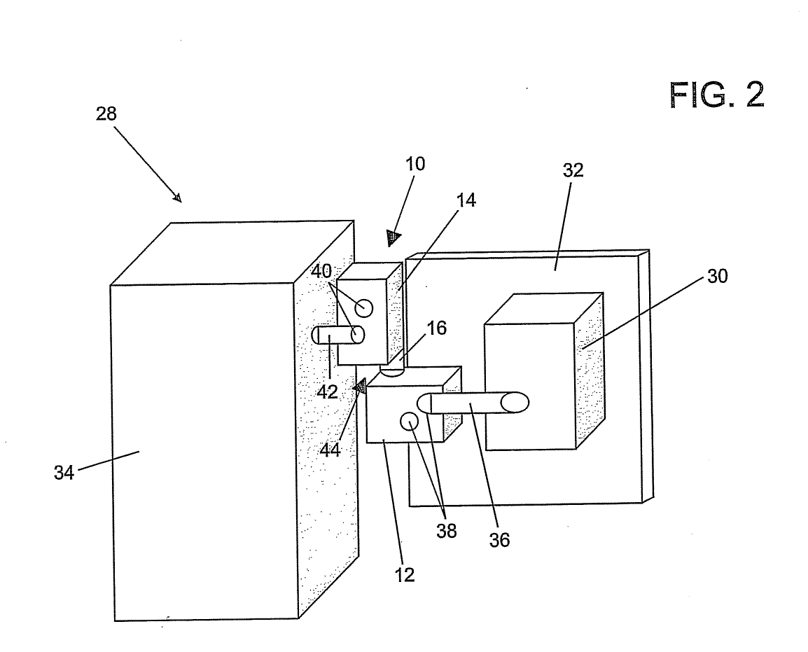

Shown in FIG. 2 is an embodiment of an electronic system 28 which includes at least one hinge 10. A first component, for example a heat exchanger 30 is provided on a door 32 of the electronic system 28. The door 32 is connected to a second component, for example a server rack 34. At least one hinge 10 is disposed connecting the door 32 to the server rack 34, is capable of structurally supporting the door 32, and allows the door 32 to open and close relative to the server rack 34. To cool the server rack 34, coolant is transported from the heat exchanger 30 through a hinge conduit 36 into the hinge 10 through an input port 38 disposed in, for example, the male portion 12 of the hinge 10. The coolant flows through the hinge 10 and exits the hinge 10 through an outlet port 40 disposed in, for example, the female portion 14 of the hinge 10. The coolant then flows through a rack conduit 42 and through the server rack 34, for example, to be cooled thereby transferring heat from the server rack 34 to the coolant. The hinge conduit 36, the hinge 10, and the rack conduit 42 together define a coolant pathway 44. The coolant then exits the server rack 34. It is to be appreciated that although a heat exchanger 30 and a server rack 34 are utilized in the embodiment shown in FIG. 2, the hinge 10 can be employed to allow the passage of coolant between any components where a relative motion is desired therebetween.

Flowing the fluid through the hinge 10 significantly decreases a length of conduit needed to connect the heat exchanger 30 to the server rack 34, because relative motion of the heat exchanger 30 and the server rack 34 does not need to be taken into account when determining a conduit length. Further, minimizing the amount of conduit utilized increases space in the electronic system 28 available for other uses. Additionally, since the hinge conduit 36 and the rack conduit 38 remain stationary when the door 32 is rotated, stress on the hinge conduit 36 and rack conduit 42, and on their connections to the heat exchanger 30 and server rack 34 are reduced, thereby increasing the useful lives of the conduits 36 and 42, and the electronic system 28.

While the preferred embodiment to the invention has been described, it will be understood that those skilled in the art, both now and in the future, may male various improvements and enhancements which fall within the scope of the claims which follow. These claims should be construed to maintain the proper protection for the invention first described.

What is claimed is:

1. A liquid cooled electronic system comprising:
a first component rotably connected to a second component via a coolant pathway, the coolant pathway including at least one hinge assembly disposed and configured to convey coolant from the first component through the hinge assembly to the second component, the hinge assembly including:
a first hinge portion in operable communication with the first component;
a second hinge portion in operable communication with the second component; and
a hinge pin disposed and configured to convey fluid therethrough, the hinge pin connecting the first hinge portion to the second hinge portion.

2. The liquid cooled electronic system of claim 1 wherein the hinge is connected to the first hinge portion and/or the second hinge portion utilizing a barb connection.

3. The liquid cooled electronic system of claim 1 wherein the hinge includes one or more o-rings to seal a connection between the hinge pin and the first hinge portion and/or the second hinge portion.

4. The liquid cooled electronic system of claim 1 wherein the hinge pin is formed integral to either of the first hinge portion or the second hinge portion.

5. The liquid cooled electronic system of claim 1 wherein the first hinge portion and/or the second hinge portion include one or more ports.

6. The liquid cooled electronic system of claim 5 wherein one or more components are connected to the one or more ports via conduit and configured to convey coolant therethrough.

7. The liquid cooled electronic system of claim 1 wherein the first component is a heat exchanger.

8. The liquid cooled electronic system of claim 1 wherein the hinge assembly is configured to be capable of at least partially structurally supporting the first component and/or the second component.

9. A method of cooling an electronic system comprising:
transporting coolant from a first component into a hinge assembly, the hinge assembly including:
a first hinge portion in operable communication with the first component;
a second hinge portion in operable communication with the second component; and
a hinge pin disposed and configured to convey fluid therethrough, the hinge pin connecting the first hinge portion to the second hinge portion;
flowing the coolant through the hinge pin and into a second component;
transferring heat from the second component into the coolant; and
removing the coolant from the second component.

10. The method of claim 9 wherein the first hinge portion and/or the second hinge portion include one or more conduit connection ports.

11. The method of claim 10 wherein one or more components are connected to the one or more conduit connection ports via conduit and configured to convey coolant therethrough.

12. The liquid cooled electronic system of claim 9 wherein the first component is a heat exchanger.
